(19) United States
(12) Patent Application Publication
(10) Pub. No.: US 2026/0324203 A1
(43) Pub. Date: Oct. 15, 2026

(54) PIXEL STRUCTURE, DISPLAY PANEL, AND FABRICATION METHOD OF DISPLAY PANEL

(71) Applicant: HKC CORPORATION LIMITED, Shenzhen, Guangdong (CN)

(72) Inventors: Qin Liang, Shenzhen, Guangdong (CN); Yangling Tang, Shenzhen, Guangdong (CN); Xiufeng Zhou, Shenzhen, Guangdong (CN); Haijiang Yuan, Shenzhen, Guangdong (CN)

(21) Appl. No.: 19/481,184

(22) PCT Filed: Oct. 28, 2023
(86) PCT No.: PCT/CN2023/127432

§ 371 Date: Nov. 4, 2025

(30) Foreign Application Priority Data
May 10, 2023 (CN) 202310520085.5

(51) Int. Cl. H10K 59/122; H10K 59/12; H10K 59/121; H10K 59/126; H10K 59/80

(52) U.S. Cl. CPC H10K 59/122; H10K 59/1201; H10K 59/121; H10K 59/126; H10K 59/80521; H10K 59/80524; H10K 59/873; H10K 59/8792

(57) ABSTRACT

A pixel structure including: an anode unit, a light emitting layer, a first cathode unit, a second cathode unit, a pixel definition layer, a first conductive unit, and a first eave structure. The pixel definition layer is arranged around the anode unit, the first conductive unit is arranged above the pixel definition layer, and the first eave structure is arranged above the first conductive unit at a side away from the anode unit. The light emitting layer covers the anode unit, the pixel definition layer, the first conductive unit, and the first eave structure. The first cathode unit is arranged above the anode unit, the second cathode unit is arranged above the first conductive unit, and the first cathode unit and the second cathode unit are not connected. An anti-peep pixel is formed by the second cathode unit, the light emitting layer, and the first conductive unit.

### CROSS-REFERENCE TO RELATED APPLICATIONS

This application is the U.S. national phase of International Application No. PCT/CN2023/127432 with an international filing date of Oct. 28, 2023, designating the U.S., now pending, and claims the priority of the Chinese patent application submitted to the CNIPA on May 10, 2023, with an application number 202310520085.5 and titled “PIXEL STRUCTURE, DISPLAY PANEL, AND FABRICATION METHOD OF DISPLAY PANEL”, the entire contents of which are incorporated by reference in this application.

### BACKGROUND

### Technical Field

The present application relates to the field of display technology, more particularly to a pixel structure, a display panel, and a fabrication method of a display panel.

### Description of Related Art

Display panels based on light emitting devices, such as organic light emitting diodes (OLEDs), have becoming increasingly and widely used in products, such as computers and mobile phones, due to the characteristics of thinness, energy saving, wide view angle, wide color gamut, and high contrast.

### SUMMARY

Since mobile phones and computers are associated with a lot of personal information, once leaked, the consequences are serious. In view of this, how to prevent peeping is a problem that requires to be solved by those skilled in the art.

In view of this, embodiments of the present application provide a pixel structure, a display panel, and a fabrication method of a display panel, in order to achieve an anti-peep function.

To achieve the above objects, in a first aspect, embodiments of the present application provide a pixel structure, comprising: an anode unit, a light emitting layer, a first cathode unit, a second cathode unit, a pixel definition layer, a first conductive unit, and a first eave structure.

The pixel definition layer is arranged around the anode unit, the first conductive unit is arranged above the pixel definition layer, and the first eave structure is arranged above the first conductive unit at a side away from the anode unit.

The light emitting layer covers above the anode unit, the pixel definition layer, the first conductive unit, and the first eave structure.

The first cathode unit is arranged above the anode unit, the second cathode unit is arranged above the first conductive unit, and the first cathode unit and the second cathode unit are not connected.

An anti-peep pixel is formed by the second cathode unit, the light emitting layer, and the first conductive unit.

As an optional implementation of the embodiment of the present application, a second conductive unit is further arranged above the first eave structure, and the second cathode unit is in connection with the second conductive unit.

As an optional implementation of the embodiment of the present application, a second eave structure is arranged above the second conductive unit.

As an optional implementation of the embodiment of the present application, an insulating column is arranged between the first cathode unit and the second cathode unit.

As an optional implementation of the embodiment of the present application, an area of the second cathode unit close to one side of the first cathode unit is etched.

As an optional implementation of the embodiment of the present application, a display pixel is formed by the first cathode unit, the light emitting layer, and the anode unit; and the anti-peep pixel is arranged around the display pixel.

As an optional implementation of the embodiment of the present application, the anti-peep pixel is an annular structure arranged around the display pixel.

As an optional implementation of the embodiment of the present application, a number of the display pixel surrounded by each annular anti-peep pixel is the same.

As an optional implementation of the embodiment of the present application, the anti-peep pixel is turned on or off by an anti-peep driving signal.

When the anti-peep pixel is turned on, an area of the light emitting layer corresponding to the second cathode unit emits light. When the anti-peep pixel is turned off, the area of the light emitting layer corresponding to the second cathode unit does not emit light.

As an optional implementation of the embodiment of the present application, a material of the first cathode unit and a material of the second cathode unit are transparent conductive metal oxides.

In a second aspect, embodiments of the present application provides a display panel, comprising: from bottom to top, a substrate base, a driving layer, an encapsulation layer, a light shielding layer, and a plurality of pixel structures according to the first aspect or any embodiment of the first aspect. The plurality of pixel structures are arranged between the driving layer and the encapsulation layer.

The light shielding layer comprises a plurality of light shielding units arranged at intervals. The plurality of light shielding units are arranged in one-to-one correspondence with a plurality of second cathode units, and each of the plurality of light shielding units is arranged above a corresponding one of the plurality of second cathode units.

As an optional implementation of the embodiment of the present application, the display panel comprises a plurality of sets of anti-peep pixel, and anti-peep pixels in a same set of anti-peep pixels are connected in series.

As an optional implementation of the embodiment of the present application, the anti-peep pixels in the same set of anti-peep pixel are controlled by a switch.

In a third aspect, embodiments of the present application provide a fabrication method of a display panel, being used to fabricate the display panel according to the second aspect or according to any embodiment of the second aspect. The method comprises:
forming a driving layer on a substrate base, and forming a plurality of anode units on the driving layer;
forming a pixel definition layer around the plurality of anode units, forming a boundary conductive layer above the pixel definition layer, in which, the boundary conductive layer comprises a plurality of first conductive units, and forming a plurality of first eave structures above the plurality of first conductive units, respectively;
forming a light emitting layer above the plurality of anode units, the pixel definition layer, the plurality of first conductive units, and the plurality of first eave structures;
forming a plurality of first cathode units in regions above the light emitting layer corresponding to the plurality of anode units, and forming plurality of second cathode units in regions above the light emitting layer corresponding to the plurality of first conductive units; and
forming an encapsulation layer on upper surfaces of the plurality of first cathode units, the plurality of second cathode units, and the plurality of first eave structures, and forming a light shielding layer above the encapsulation layer.

The technical solution provided by the embodiment of the present application includes: the anode unit, the light emitting layer, the first cathode unit, the second cathode unit, the pixel definition layer, the first conductive unit and the first eave structure. The pixel definition layer is arranged around the anode unit, the first conductive unit is arranged above the pixel definition layer, and the first eave structure is arranged above the first conductive unit at the side away from the anode unit. The light emitting layer covers above the anode unit, the pixel definition layer, the first conductive unit, and the first eave structure. The first cathode unit is arranged above the anode unit, the second cathode unit is arranged above the first conductive unit, and the first cathode unit and the second cathode unit are not connected. The anti-peep pixel is formed by the second cathode unit, the light emitting layer, and the first conductive unit. The anti-peep pixel and the display pixel (corresponding to the first cathode unit, the light emitting layer and the anode unit) of the display panel can emit a mixed light, thereby making the display panel display different colors, interfering with information reading, and realizing the anti-peep function. Moreover, compared with the prior art that requires the fabrication of new anodes and cathodes of anti-peep pixels, the technical solution of the present application directly reuses the first conductive unit as the anode of the anti-peep pixel, which not only saves space, but also reduces the photomask corresponding to the anode of the anti-peep pixel, thereby reducing the manufacturing cost. In addition, the first eave structure is arranged above the first conductive unit at a side away from the anode unit, that is, the region above the first conductive unit at a side close to the anode unit is not shielded, which can increase the display area of the anti-peep pixel and improve the aperture ratio of the anti-peep pixel, thereby achieving a better anti-peep effect.

### BRIEF DESCRIPTION OF THE DRAWINGS

In order to more clearly illustrate the technical solutions in the embodiments of the present application, the drawings that need to be used in the description of the embodiments will be briefly described hereinbelow. Obviously, the accompanying drawings in the following description are only some embodiments of the present application. For those skilled in the art, other drawings can be obtained based on these drawings without creative work.

FIG. 1 is a structural schematic diagram of a display panel provided in a first embodiment of the present application;

FIG. 2 is a structural schematic diagram of a display panel provided by a second embodiment of the present application;

FIG. 3 is a schematic diagram showing a positional relationship between anti-peep pixels and display pixels provided in the second embodiment of the present application;

FIG. 4 is another schematic diagram showing a positional relationship between anti-peep pixels and display pixels provided in the second embodiment of the present application;

FIG. 5 is another schematic diagram of a positional relationship between anti-peep pixels and display pixels provided in the second embodiment of the present application;

FIG. 6 is another schematic diagram showing a positional relationship between anti-peep pixels and display pixels provided in the second embodiment of the present application;

FIG. 7 is another schematic diagram showing a positional relationship between anti-peep pixels and display pixels provided in the second embodiment of the present application; and

FIG. 8 is a flow chart of a fabrication method of a display panel provided in a second embodiment of the present application.

Explanation of the reference numerals are as follows:
10: substrate base; 20: driving layer;
30: pixel structure;
31: anti-peep pixel; 32: display pixel;
40: encapsulation layer; 50: light shielding layer;
301: anode unit; 302: light emitting layer;
303: first cathode unit; 304: second cathode unit;
305: pixel definition layer; 306: first conductive unit;
307: first eave structure; 308: second conductive unit;
309: second eave structure; 310: insulating column; and
501: light shielding unit.

### DETAILED DESCRIPTION OF THE EMBODIMENTS

In order to make the purpose, technical solution and advantages of the present application clearer, embodiments of the present application will be further described in detail in conjunction with the accompanying drawings.

Terms used in the implementation of the embodiments of the present application are only used to explain the specific embodiments of the present application, and are not intended to limit the present application. The following specific embodiments may be combined with each other, and the same or similar concepts or processes may not be repeated in some embodiments.

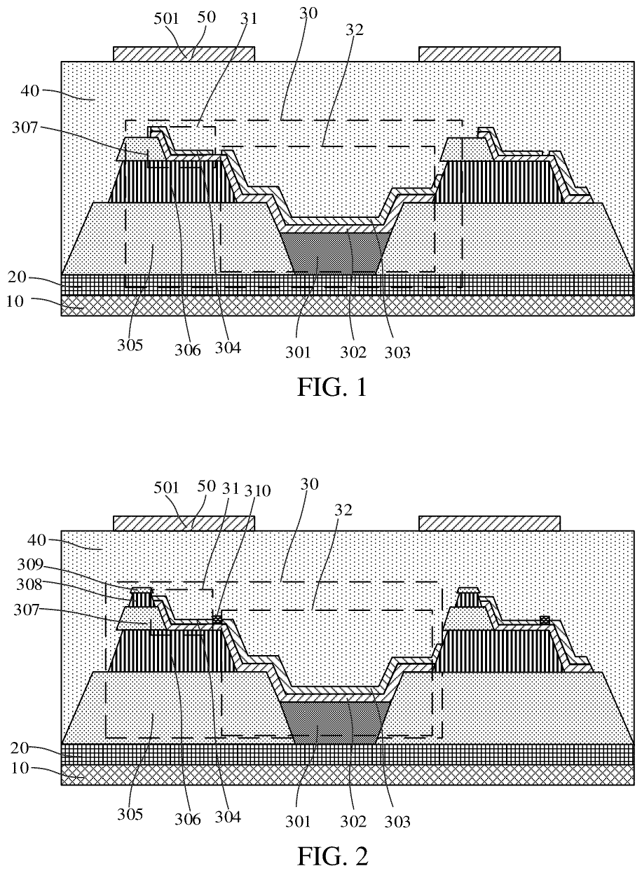

FIG. 1 is a structural schematic diagram of a display panel provided in a first embodiment of the present application. As shown in FIG. 1, the display panel provided in the embodiment of the present application may include a substrate base 10, a driving layer 20, a pixel structure 30, an encapsulation layer 40, and a light shielding layer 50 arranged from bottom to top.

The substrate base 10 may be a rigid substrate or a flexible substrate. A material of the rigid substrate may be glass, and a material of the flexible substrate may be a polymer material, such as a polyimide.

The driving layer 20 is arranged above the substrate base 10 and may include a plurality of thin film transistors (TFTs) to drive pixel structures 30 to emit light.

Each pixel structure 30 may include: an anode unit 301, a light emitting layer 302, a first cathode unit 303, a second cathode unit 304, a pixel definition layer 305, a first conductive unit 306, and a first eave structure 307.

The anode unit 301 is arranged above the driving layer 20. A material of the anode unit 301 may be a conductive metal oxide, such as indium tin oxide (ITO) and the like. A material of the anode unit 301 may also be a metal, such as aluminum (Al), gold (Au), silver (Ag), and the like.

The pixel definition layer 305 is arranged around a plurality of anode units 301. The material of the pixel definition layer 305 may be organic polyimide, or inorganic SiNx, SiOx, SiOxNx, or the like.

The first conductive unit 306 is arranged above the pixel definition layer 305. A material of the first conductive unit 306 may be a metal, such as copper, silver, and the like.

The first cathode unit 303, the light emitting layer 302, and the anode unit 301 form a display pixel 32, and the second cathode unit 304, the light emitting layer 302, and the first conductive unit 306 form an anti-peep pixel 31. The anti-peep pixel 31 can emit red light, green light, blue light, yellow light, white light, and any other light having a high brightness and a strong interference, such that the anti-peep pixel 31 and the display pixel 32 of the display panel emit a mixed light, thereby making the display panel display different colors, interfering with information reading, and realizing the anti-peep function. In addition, by directly reusing the first conductive unit 306 as the anode of the anti-peep pixel 31, not only can the space be saved, but also the fabrication of the photomask corresponding to the anode of the anti-peep pixel 31 can be reduced, thereby reducing the manufacturing cost.

The anti-peep pixel 31 can be turned on or off by an anti-peep driving signal, so that when in normal use, the user can choose to turn off the anti-peep function, and when entering a password or other operations involving the personal information, the user can choose to turn on the anti-peep function, which can greatly improve the user experience.

For each anti-peep pixel 31, when the anti-peep pixel 31 is turned on, an area of the light emitting layer 302 corresponding to the second cathode unit 304 emits light, which forms a mixed light together with a light emitted by the adjacent display pixel 32 to achieve the anti-peep function; and when the anti-peep pixel 31 is turned off, the area of the light emitting layer 302 corresponding to the second cathode unit 304 does not emit light, and the display panel displays normally.

All anti-peep pixels 31 can be connected in series, so that all the anti-peep pixels 31 can be turned on or off by only one switch, which can greatly reduce wiring and reduce costs. Alternatively, a plurality of anti-peep pixels 31 in different regions may form a set of anti-peep pixels 31, and the anti-peep pixels 31 in the same set of anti-peep pixels 31 may be connected in series, and the anti-peep pixels 31 in the same set of anti-peep pixels 31 may be controlled by a switch, thereby realizing a partitioned anti-peep function of the display panel.

A first eave structure 307 is arranged above the first conductive unit 306 at a side away from the anode unit 301, so that a region above the first conductive unit 306 at a side close to the anode unit 301 will not be shielded, so as to increase the display area of the anti-peep pixel 31 and improve an aperture ratio of the anti-peep pixel 31, thereby achieving a better anti-peep effect.

The light emitting layer 302 covers the anode unit 301, the pixel definition layer 305, the first conductive unit 306, and the first eave structure 307. The light emitting layer 302 may include a plurality of light emitting materials of different colors, such as red, green, and blue.

The first cathode unit 303 is arranged above the anode unit 301, and the second cathode unit 304 is arranged above the first conductive unit 306. A material of the first cathode unit 303 can be a metal material, such as aluminum (Al), gold (Au), silver (Ag), and the like. A material of the first cathode unit 303 can also be a transparent conductive metal oxide, and the like.

The material of the second cathode unit 304 can be the same as that of the first cathode unit 303. A side of the first cathode unit 303 away from the second cathode unit 304 is in connection with a conductive unit of an adjacent display pixel 32. The first cathode unit 303 and the second cathode unit 304 are not connected.

Specifically, the first cathode unit 303 and the second cathode unit 304 can be disconnected, by etching an area of the second cathode unit 304 close to a side of the first cathode unit 303 during the fabrication process, or by providing an insulating column 310 between the first cathode unit 303 and the second cathode unit 304, as shown in FIG. 2.

The encapsulation layer 40 is arranged on the upper surfaces of the first cathode unit 303, the second cathode unit 304, and the first eave structure 307. The material of the encapsulation layer 40 may include silicon nitride, silicon oxynitride, or a combination thereof.

The light shielding layer 50 is arranged above the encapsulation layer 40. A material of the light shielding layer 50 may be chromium, chromium oxide, and a black resin.

The light shielding layer 50 may include a plurality of light shielding units 501 arranged at intervals. The plurality of light shielding units 501 and the plurality of second cathode units 304 are arranged in one-to-one correspondence. Each of the plurality of light shielding units 501 is arranged above a corresponding one of the plurality of second cathode units 304. A projected area of each light shielding unit 501 on the substrate base 10 may be larger than the projected area of a corresponding second cathode unit 304 on the substrate base 10. In this way, when the anti-peep pixel 31 is turned on, a light mixing angle can be reduced in the direction perpendicular to the substrate base 10, and a normal display angle can be increased. In this way, even if the user's view angle is not perpendicular to the display panel, as long as the view angle is within a normal display angle of the display panel, the display panel can display normally within such view angle, thereby improving the user experience.

FIG. 2 is a structural schematic diagram of a display panel provided by a second embodiment of the present application. As shown in FIG. 2, an insulating column 310 is arranged between the first cathode unit 303 and the second cathode unit 304, and a second conductive unit 308 is further arranged above the first eave structure 307. Each second cathode unit 304 is in connection with a corresponding second conductive unit 308. The second conductive unit 308 can output a fixed voltage to the second cathode unit 304 to reduce the voltage drop caused by the wiring of the second cathode unit 304. A material of the second conductive unit 308 can be copper, silver and other metals.

A second eave structure 309 can also be arranged above the second conductive unit 308. The second eave structure 309 is used to protect a joint area between the second cathode unit 304 and the second conductive unit 308 during a maskless evaporation, so that the joint area of the second cathode unit 304 and the second conductive unit 308 is not affected by the etching solution during photolithography.

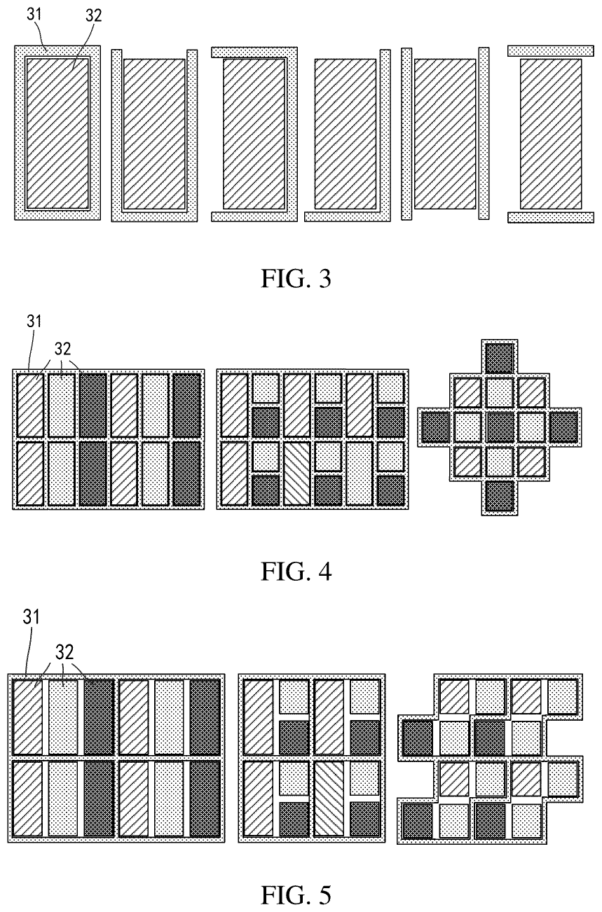

FIG. 3 is a schematic diagram showing a positional relationship between anti-peep pixels and display pixels provided in the second embodiment of the present application. As shown in FIG. 3, the colors of the anti-peep pixels 31 can be different from the colors of the display pixels 32. The anti-peep pixels 31 can be arranged around the display pixels 32, or in certain directions of the display pixels 32. In this way, at least one or two anti-peep pixels 31 are arranged between adjacent display pixels 32, thereby achieving an anti-peeping effect.

FIG. 4 is another schematic diagram showing a positional relationship between anti-peep pixels and display pixels provided in the second embodiment of the present application. As shown in FIG. 4, each anti-peep pixel 31 can form an annular structure around a plurality of sub-pixels. Such an arrangement can maximize the aperture ratio of the anti-peep pixels 31 to achieve a better anti-peeping effect.

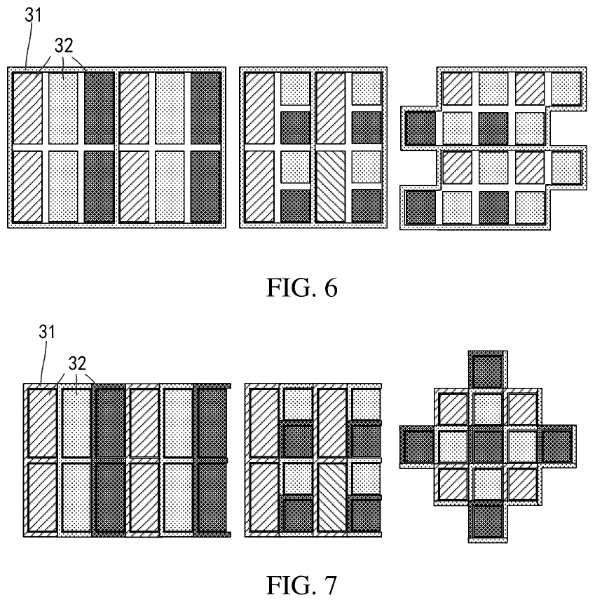

FIG. 5 is another schematic diagram of a positional relationship between anti-peep pixels and display pixels provided in the second embodiment of the present application. As shown in FIG. 5, each anti-peep pixel 31 can also form an annular structure around a plurality of display pixels 32 (a display pixel 32 can include a plurality of sub-pixels, and the plurality of sub-pixels can be red sub-pixels, green sub-pixels, blue sub-pixels, and the like), so that the anti-peep pixels 31 can minimize the impact on the aperture ratio of the display pixels 32 while preventing peeping.

To further reduce the impact on the aperture ratio of the display pixels 32, each anti-peep pixel 31 can also surround a plurality of display pixels 32 as shown in FIG. 6.

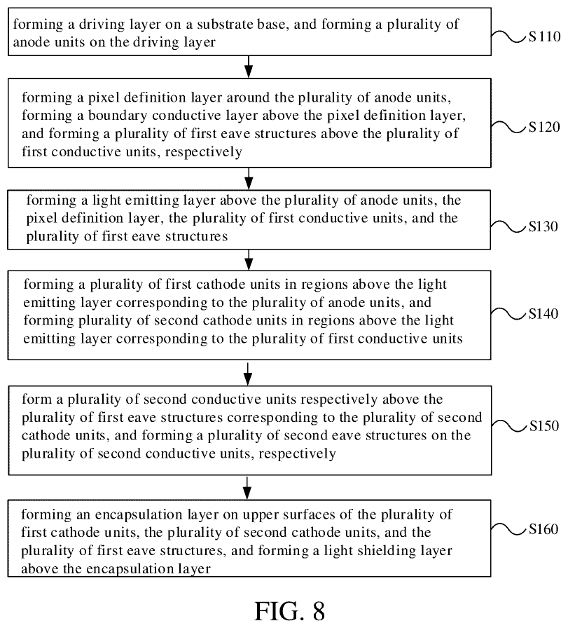

FIG. 7 is another schematic diagram showing a positional relationship between anti-peep pixels and display pixels provided in the second embodiment of the present application. As shown in FIG. 7, the colors of the anti-peep pixels 31 can also be the same as the colors of the corresponding adjacent display pixels 32, thereby forming more types of anti-peeping effects.

FIG. 8 is a flow chart of a fabrication method of a display panel provided in a second embodiment of the present application. As shown in FIG. 8, the fabrication method of the display panel provided in the embodiment of the present application may be performed by the following steps:

In step S110, a driving layer is formed on a substrate base, and a plurality of anode units are formed on the driving layer.

Specifically, the driving layer 20 may be firstly formed on the substrate base 10, and then a plurality of anode units 301 may be formed on the driving layer 20 by a sputtering process.

In step S120, a pixel definition layer is formed around the plurality of anode units, and a boundary conductive layer is formed above the pixel definition layer, in which, the boundary conductive layer comprises a plurality of first conductive units, and a plurality of first eave structures are formed above the plurality of first conductive units, respectively.

Specifically, a pixel definition layer 305 may be formed around the plurality of anode units 301 by plasma enhanced chemical vapor deposition, sputtering, atomic layer deposition and other processes, and then a boundary conductive layer may be formed above the pixel definition layer 305. The boundary conductive layer may include a plurality of first conductive units 306, and a plurality of first eave structures 307 may be formed above the plurality of first conductive units 306, respectively.

S130, a light emitting layer is formed above the plurality of anode units, the pixel definition layer, the plurality of first conductive units, and the plurality of first eave structures.

Specifically, the evaporation process can be used to form the light emitting layer 302 on regions where the plurality of anode units 301, the pixel definition layer 305, the plurality of first conductive unit 306 and the plurality of first eave structure 307 are not covered.

In step S140, a plurality of first cathode units are formed in regions above the light emitting layer corresponding to the plurality of anode units, and a plurality of second cathode units are formed in regions above the light emitting layer corresponding to the plurality of first conductive units.

Specifically, a cathode layer can be formed above the light emitting layer 302 by using the evaporation process, and then a side of the cathode layer above the first conductive unit 306 close to a corresponding anode units 301 is etched to form a plurality of first cathode unit 303 and a plurality of second cathode units 304 that are not interconnected.

Further, an insulating column 310 can be provided between each of the plurality of first cathode units 303 and a corresponding one of the plurality of second cathode units 304 to prevent the plurality of first cathode unit 303 and the plurality of second cathode unit 304 from being interconnected.

S150, a plurality of second conductive units are respectively formed above the plurality of first eave structures corresponding to the plurality of second cathode units, and a plurality of second eave structures are formed on the plurality of second conductive units, respectively.

Specifically, one of a plurality of second conductive units 308 can be formed above each of the plurality of first eave structures 307 corresponding to a respective one of the plurality of second cathode units 304, so that each of the plurality second cathode unit 304 is in connection with a corresponding second conductive unit 308, and then a plurality of second eave structures 309 are formed above the plurality of second conductive units 308, respectively.

S160, an encapsulation layer is formed on upper surfaces of the plurality of first cathode units, the plurality of second cathode units, the plurality of first eave structures, and the plurality of second eave structures, and a light shielding layer is formed above the encapsulation layer.

Specifically, processes including plasma enhanced chemical vapor deposition, sputtering, atomic layer deposition can be used to form the encapsulation layer 40 on the upper surface of the plurality of first cathode units 303, the plurality of second cathode units 304, the plurality of first eave structures 307, and the plurality of second eave structure 309, and then the plasma enhanced chemical vapor deposition process can be used to form a light shielding layer 50 above the encapsulation layer 40, and a material of the light shielding layer 50 can be chromium, chromium oxide, a black resin, and the like.

The light shielding layer 50 may include a plurality of light shielding units 501 arranged at intervals, the plurality of light shielding units 501 and the plurality of second cathode units 304 are arranged in one-to-one correspondence, and each of plurality of light shielding units 501 is arranged above a corresponding one of the plurality of second cathode units 304.

The technical solution provided by the embodiment of the present application includes: the anode unit, the light emitting layer, the first cathode unit, the second cathode unit, the pixel definition layer, the first conductive unit and the first eave structure. The pixel definition layer is arranged around the anode unit, the first conductive unit is arranged above the pixel definition layer, and the first eave structure is arranged above the first conductive unit at the side away from the anode unit. The light emitting layer covers above the anode unit, the pixel definition layer, the first conductive unit, and the first eave structure. The first cathode unit is arranged above the anode unit, the second cathode unit is arranged above the first conductive unit, and the first cathode unit and the second cathode unit are not connected. The anti-peep pixel is formed by the second cathode unit, the light emitting layer, and the first conductive unit. The anti-peep pixel and the display pixel (corresponding to the first cathode unit, the light emitting layer and the anode unit) of the display panel can emit a mixed light, thereby making the display panel display different colors, interfering with information reading, and realizing the anti-peep function. Moreover, compared with the prior art that requires the fabrication of new anodes and cathodes of anti-peep pixels, the technical solution of the present application directly reuses the first conductive unit as the anode of the anti-peep pixel, which not only saves space, but also reduces the photomask corresponding to the anode of the anti-peep pixel, thereby reducing the manufacturing cost. In addition, the first eave structure is arranged above the first conductive unit at a side away from the anode unit, that is, the region above the first conductive unit at a side close to the anode unit is not shielded, which can increase the display area of the anti-peep pixel and improve the aperture ratio of the anti-peep pixel, thereby achieving a better anti-peep effect.

In the above-mentioned embodiments, the descriptions of the embodiments have their own emphases, and for parts that are not detailed or recorded in a certain embodiment, relevant descriptions of other embodiments can be referred to.

In addition, the size ratio relationship among the various components in the drawings is only schematic, which does not reflect the actual size ratio relationship between the various components.

In the description of the present application, orientations or positional relationships indicated by the terms “central”, “longitudinal”, “transverse”, “upper”, “lower”, “front”, “rear”, “left”, “right”, “vertical” “horizontal”, “top”, “bottom”, “inner”, “outer”, and the like are based on the orientations or positional relationships shown in the drawings, and are only for the convenience of describing the present application and simplifying the description, rather than indicating or implying that a referenced device or element must have a particular orientation, or be constructed and operated in a particular orientation, and should therefore not be construed as limiting the present application.

In the description of the present application, it should be noted that unless otherwise specified and limited, the terms “installation” and “connection” should be understood in a broad sense, for example, it can be a fixed connection or a detachable connection, or an integral connection; it can be mechanically connected or electrically connected; it can be directly connected or indirectly connected through an intermediary, and it can be the internal communication of two components. Those skills in the art can understand the specific meanings of the above terms in the present application based on specific situations.

It should be understood that when used in this specification and the appended claims, the term “comprising” indicates the presence of described features, integers, steps, operations, elements, and/or components, but does not exclude existence or addition of one or more other features, wholes, steps, operations, elements, components and/or collections thereof.

In the description of the present application, unless otherwise specified, “/” means that the objects associated with each other are an “or” relationship, for example, A/B can mean A or B; “and/or” in the present application is only an association relationship describing associated objects, which means that there can be three kinds of relationships, for example, A and/or B, which can mean: A exists alone, A and B exist at the same time, and B exists alone, in which, A and B can be singular or plural.

In the description of the present application, unless otherwise specified, “plurality” means two or more than two. “At least one of the following” or similar expressions refer to any combination of these items, including any combination of single items or plural items. For example, at least one of a, b, or c can represent: a, b, c, a-b, a-c, b-c, or a-b-c, in which, a, b, c can be singular or plural.

In addition, in the description of the specification and the appended claims of the present application, the terms “first”, “second”, “third”, and the like are used to distinguish similar objects, and not necessarily used to describe a specific order or sequence order. It is to be understood that the terms so used are interchangeable under appropriate circumstances such that the embodiments described herein can be practiced in sequences other than those illustrated or described herein.

Reference to “an embodiment” or “some embodiments” or the like in the specification of the present application means that a particular feature, structure, or characteristic described in connection with such embodiment is included in one or more embodiments of the present application. Thus, appearances of the phrases “in an embodiment”, “in some embodiments”, “in other embodiments”, “in still other embodiments”, and the like in various places in this specification are not necessarily all refer to the same embodiment, but mean “one or more but not all embodiments”, unless specifically stated otherwise.

Finally, it should be noted that: the above embodiments are only used to illustrate the technical solutions of the present application, rather than making limitations on the technical solutions; although the application has been described in detail with reference to the foregoing embodiments, those skills in the art should understand that: it is still possible to modify the technical solutions described in the foregoing embodiments, or perform equivalent replacements for some or all of the technical features; and these modifications or replacements do not make the essence of the corresponding technical solutions deviate from the scope of technical solutions of the various embodiments of the present application.

What is claimed is:

1. A pixel structure, comprising: an anode unit, a light emitting layer, a first cathode unit, a second cathode unit, a pixel definition layer, a first conductive unit, and a first eave structure;
the pixel definition layer is arranged around the anode unit, the first conductive unit is arranged above the pixel definition layer, and the first eave structure is arranged above the first conductive unit at a side away from the anode unit;
the light emitting layer covers above the anode unit, the pixel definition layer, the first conductive unit, and the first eave structure;
the first cathode unit is arranged above the anode unit, the second cathode unit is arranged above the first conductive unit, and the first cathode unit and the second cathode unit are not connected; and
an anti-peep pixel is formed by the second cathode unit, the light emitting layer, and the first conductive unit.

2. The pixel structure according to claim 1, wherein a second conductive unit is further arranged above the first eave structure, and the second cathode unit is in connection with the second conductive unit.

3. The pixel structure according to claim 2, wherein a second eave structure is arranged above the second conductive unit.

4. The pixel structure according to claim 1, wherein an insulating column is arranged between the first cathode unit and the second cathode unit.

5. The pixel structure according to claim 1, wherein an area of the second cathode unit close to one side of the first cathode unit is etched.

6. The pixel structure according to claim 1, wherein a display pixel is formed by the first cathode unit, the light emitting layer, and the anode unit; and the anti-peep pixel is arranged around the display pixel.

7. The pixel structure according to claim 6, wherein the anti-peep pixel is an annular structure arranged around the display pixel.

8. The pixel structure according to claim 7, wherein a number of the display pixel surrounded by each annular anti-peep pixel is the same.

9. The pixel structure according to claim 1, wherein the anti-peep pixel is turned on or off by an anti-peep driving signal;
when the anti-peep pixel is turned on, an area of the light emitting layer corresponding to the second cathode unit emits light; and
when the anti-peep pixel is turned off, the area of the light emitting layer corresponding to the second cathode unit does not emit light.

10. The pixel structure according to claim 1, wherein a material of the first cathode unit and a material of the second cathode unit are transparent conductive metal oxides.

11. A display panel, comprising: from bottom to top, a substrate base, a driving layer, an encapsulation layer, a light shielding layer, and a plurality of pixel structures according to claim 1;
wherein
the plurality of pixel structures are arranged between the driving layer and the encapsulation layer;
the light shielding layer comprises a plurality of light shielding units arranged at intervals, wherein the plurality of light shielding units are arranged in one-to-one correspondence with a plurality of second cathode units, and each of the plurality of light shielding units is arranged above a corresponding one of the plurality of second cathode units.

12. The display panel according to claim 11, wherein the display panel comprises a plurality of sets of anti-peep pixel, and anti-peep pixels in a same set of anti-peep pixels are connected in series.

13. The display panel according to claim 12, wherein the anti-peep pixels in the same set of anti-peep pixel are controlled by a switch.

14. The display panel according to claim 11, wherein a projected area of each of the plurality of light shielding layers on the substrate base is larger than a projected area of a corresponding one of the plurality of second cathode units on the substrate base.

15. A fabrication method of a display panel, being used to fabricate the display panel according to claim 11, wherein the method comprises:
forming a driving layer on a substrate base, and forming a plurality of anode units on the driving layer;
forming a pixel definition layer around the plurality of anode units, forming a boundary conductive layer above the pixel definition layer, wherein the boundary conductive layer comprises a plurality of first conductive units, and forming a plurality of first eave structures above the plurality of first conductive units, respectively;
forming a light emitting layer above the plurality of anode units, the pixel definition layer, the plurality of first conductive units, and the plurality of first eave structures;
forming a plurality of first cathode units in regions above the light emitting layer corresponding to the plurality of anode units, and forming plurality of second cathode units in regions above the light emitting layer corresponding to the plurality of first conductive units; and
forming an encapsulation layer on upper surfaces of the plurality of first cathode units, the plurality of second cathode units, and the plurality of first eave structures, and forming a light shielding layer above the encapsulation layer.

16. The display panel according to claim 11, wherein a second conductive unit is further arranged above the first eave structure, and the second cathode unit is in connection with the second conductive unit.

17. The display panel according to claim 12, wherein a second eave structure is arranged above the second conductive unit.

18. The display panel according to claim 11, wherein an insulating column is arranged between the first cathode unit and the second cathode unit.

19. The display panel according to claim 11, wherein an area of the second cathode unit close to one side of the first cathode unit is etched.

20. The display panel according to claim 11, wherein a display pixel is formed by the first cathode unit, the light emitting layer, and the anode unit; and the anti-peep pixel is arranged around the display pixel.
